(19) United States
(12) Patent Application Publication
(10) Pub. No.: US 2016/0125954 A1
(43) Pub. Date: May 5, 2016

(54) SHIFT REGISTER AND A GATE DRIVING DEVICE

(71) Applicants: Boe Technology Group Co., Ltd., Beijing (CN); Hefei Xinsheng Optoelectronics Technology Co., Ltd., Anhui (CN)

(72) Inventor: Xiaofang Gu, Beijing (CN)

(21) Appl. No.: 14/744,258

(22) Filed: Jun. 19, 2015

(30) Foreign Application Priority Data
Nov. 3, 2014 (CN) 201410614091.8

(51) Int. Cl. G11C 19/28; G09G 3/36

(52) U.S. Cl. CPC G11C 19/28; G09G 3/3648; G09G 2310/0286

(57) ABSTRACT

The present invention discloses a shift registor and a gate driving device, the shift register comprising: an input module for providing an input signal to a pull-up node; an output module for storing the input signal and providing a first clock signal to an output terminal; a reset module for providing a level signal to the pull-up node; a pull-up module for providing a second clock signal to a pull-down node; a first pull-down module for providing the level signal to the pull-down node; and a second pull-down module for providing the level signal to the pull-up node and providing the level signal to the output terminal.

### RELATED APPLICATIONS

The present application claims the benefit of Chinese Patent Application No. 201410614091.8, filed Nov. 3, 2014, the entire disclosure of which is incorporated herein by reference.

### FIELD OF THE INVENTION

The present invention relates to the technical field of display manufacture, particularly to a shift register and a gate driving device.

### BACKGROUND OF THE INVENTION

Panel displays have been widely used in electronic products such as televisions, mobile phones, displays due to its advantages of light weight, less thickness and low power consumption. The panel display comprises a pixel matrix constituted by intersections of multiple rows of scan lines and multiple columns of data lines, the pixel matrix scans the respective pixels successively using the method of row-by-row scanning (i.e., converting the input clock signal into a turn-on/turn-off voltage through a gate driving circuit, and applying it to respective gate lines of an array substrate in sequence), then latches the input display data and the clock signal at regular time and in proper sequence through a data driving circuit, and converts it into an analog signal, which is then input to the data line of the substrate and converted into a current to drive the pixel matrix.

The gate driving circuit (i.e., the driving circuit of the row scan lines) is generally realized by integrating a gate driving device formed by a plurality of cascaded shift registers (SR) into a liquid crystal panel (i.e., Gate driver On Array, GOA). Wherein, the gate driving circuit can be arranged in the array substrate in the package manner of Chip On Film (COF) or Chip On Glass (COG), and can also be arranged in the array substrate in the manner of using thin film transistors (TFT) to constitute an integrated circuit unit. For a panel display, the GOA design of the gate driver can simplify the fabricating process, hence, it not only reduces the fabrication cost of the panel display, but also shortens the fabrication period in a certain degree. So, the GOA technology has been widely used in manufacture of panel displays in recent years. However, the life time and the output stability of the GOA have been the import issues in GOA design all through.

FIG. 1 is a structural schematic view of a most basic shift register unit of the existing GOA technology, wherein, FIG. 1 shows the most basic shift register unit of the GOA. The shift register as shown in FIG. 1 comprises four thin film transistors T1 to T4 and a capacitor, moreover, the shift register comprises four input ends and an output end, i.e., the input end for receiving the first clock signal CLK, the input end INPUT of the input module, the output end OUTPUT of the output module, the input end RESET of the reset module and the input end VSS for the level signal. In actual applications, the transistor T2 in the shift register unit may cause the output end OUTPUT to generate noise and cannot work stably for a long time due to the influence of the coupling voltage generated to it by the first clock signal CLK.

At present, there have been some GOA-design related patents that have provided solutions and can solve the above problems essentially. FIG. 2 is a circuit schematic view of a shift register unit consisting of twelve TFTs and one capacitor in the prior art. The circuit as shown in FIG. 2 comprises twelve amorphous silicon made TFTs M1-M6 and M8-M13 and a capacitor C1, moreover, the shift register comprises five input ends and an output end, i.e., the input end for receiving the first clock signal CLK, the input end for receiving the second clock signal CLKB, the input end INPUT of the input module, the output end OUTPUT of the output module, the input end RESET of the reset module, the input end VSS for the level signal. The shift register further comprises a first node PU, a second node PD and a third node PD_CN. Compared with the conventional GOA shift register, the shift register as shown in FIG. 2 can mitigate 50% of the drift of the threshold voltage of the TFT, and reduce the power consumption of the whole circuit. However, the circuit as shown in FIG. 2 still has the defects such as relatively complex circuit structure.

At present, panel displays of small size generally has the requirement of narrow frames, the circuit structure in FIG. 2 needs a very large space, hence, it cannot meets the requirement on narrow frames. In addition, the shift register designed in FIG. 2 still has a relatively large drift of threshold voltage for an oxide TFT.

To sum up, the shift register in the prior art still has a relatively large drift of the threshold voltage, moreover, the shift register occupies a very large space and cannot meet the requirement of the panel display on narrow frames.

### SUMMARY OF THE INVENTION

The embodiment of the present invention provides a shift register and a gate driving device for reducing the duty cycle of the clock signal in the shift register, thereby mitigating drift of threshold voltage of the thin film transistors in the shift register. Since the circuit structure of the shift register is simplified, the space occupied by the shift register is reduced, thereby meeting the requirement of the small-size panel display on narrow frames.

One aspect of the present invention provides a shift register, comprising: an output module, a reset module, a pull-up module, a first pull-down module and a second pull-down module. The input module, in response to an input signal, is arranged to provide the input signal to a pull-up node, wherein the pull-up node is an output node of the input module. The output module is arranged to store the input signal and in response to a voltage of the pull-up node, provide a first clock signal to an output terminal of the shift register. The reset module, in response to a reset signal, is arranged to provide a level signal to the pull-up node. The pull-up module, in response to a fourth clock signal, is arranged to provide the fourth clock signal to a pull-down node, wherein the pull-down node is an output node of the pull-up module. The first pull-down module, in response to the input signal, the voltage of the pull-up node and a second clock signal, is arranged to provide the level signal to the pull-down node. The second pull-down module, in response to the voltage of the pull-down node, is arranged to provide the level signal to the pull-up node, and in response to the voltage of the pull-down node and a third clock signal, provide the level signal to the output terminal.

According to an embodiment of the present invention, a duty cycle of each of the first clock signal to the fourth clock signal may be 25%, and the first clock signal to the fourth clock signal are of high level successively.

The shift register according to the embodiment of the present invention adopts the manner of inputting four clock signals, and the duty cycle of each clock signal is 25%, thereby mitigating drift of the threshold voltage of the thin film transistor. In addition, the amount of the thin film transistors is reduced, thereby the circuit structure is simplified, so as to meet the requirement of the small-size panel display on narrow frames.

According to an embodiment of the present invention, the input module may comprise a first thin film transistor, a gate and a source of the first thin film transistor being connected to an input end of the input module, a drain of the first thin film transistor being connected to the output node of the input module.

According to an embodiment of the present invention, the output module may comprise: a second thin film transistor, a gate of the second thin film transistor being connected to the pull-up node, a source of the second thin film transistor being connected to an input end for the first clock signal, a drain of the second thin film transistor being connected to the output terminal; and a capacitor connected between the pull-up node and the output terminal.

According to an embodiment of the present invention, the reset module may comprise: a third thin film transistor, a gate of the third thin film transistor being connected to an input end of the reset module, a source of the third thin film transistor being connected to the pull-up node, a drain of the third thin film transistor being connected to an input end for the level signal.

According to an embodiment of the present invention, the pull-up module may comprise: a fourth thin film transistor, a gate and a source of the fourth thin film transistor being connected to an input end for the fourth clock signal, a drain of the fourth thin film transistor being connected to the output node of the pull-up module.

According to an embodiment of the present invention, the first pull-down module may comprise: a fifth thin film transistor, a gate of the fifth thin film transistor being connected to the input end of the input module, a source of the fifth thin film transistor being connected to the pull-down node, a drain of the fifth thin film transistor being connected to the input end for the level signal; a sixth thin film transistor, a gate of the sixth thin film transistor being connected to the pull-up node, a source of the sixth thin film transistor being connected to the pull-down node, a drain of the sixth thin film transistor being connected to the input end for the level signal; and a seventh thin film transistor, a gate of the seventh thin film transistor being connected to an input end for the second clock signal, a source of the seventh thin film transistor being connected to the pull-down node, a drain of the seventh thin film transistor being connected to the input end for the level signal.

According to an embodiment of the present invention, the second pull-down module may comprise: an eighth thin film transistor, a gate of the eighth thin film transistor being connected to the pull-down node, a source of the eighth thin film transistor being connected to the pull-up node, a drain of the eighth thin film transistor being connected to the input end for the level signal; a ninth thin film transistor, a gate of the ninth thin film transistor being connected to the pull-down node, a source of the ninth thin film transistor being connected to the output terminal, a drain of the ninth thin film transistor being connected to the input end for the level signal; and a tenth thin film transistor, a gate of the tenth thin film transistor being connected to an input end for the third clock signal, a source of the tenth thin film transistor being connected to the output terminal, a drain of the tenth thin film transistor being connected to the input end for the level signal.

The other aspect of the present invention provides a gate driving device, comprising cascaded shift registers according to respective embodiments of the present invention.

According to an embodiment of the present invention, except that an input end of an input module of a first stage of shift register is connected with a first start signal, the input end of the input module of each odd stage of shift register is connected with the output terminal of a previous odd stage of shift register, and the input end of the reset module of each odd stage of shift register is connected with the output terminal of a next odd stage of shift register, and except that an input end of an input module of a second stage of shift register is connected with a second start signal, the input end of the input module of each even stage of shift register is connected with the output terminal of a previous even stage of shift register, and the input end of the reset module of each even stage of shift register is connected with the output terminal of a next even stage of shift register.

### BRIEF DESCRIPTION OF DRAWINGS

FIG. 1 is a structural schematic view of a most basic shift register unit of the existing GOA technology;

FIG. 2 is a structural schematic view of the existing shift register consisting of twelve TFTs and one capacitor;

FIG. 3 is a structural schematic view of a shift register according to an embodiment of the present invention;

FIG. 4 is a structural schematic view of a gate driving device according to an embodiment of the present invention;

FIG. 5 is a logic timing diagram of a shift register according to an embodiment of the present invention.

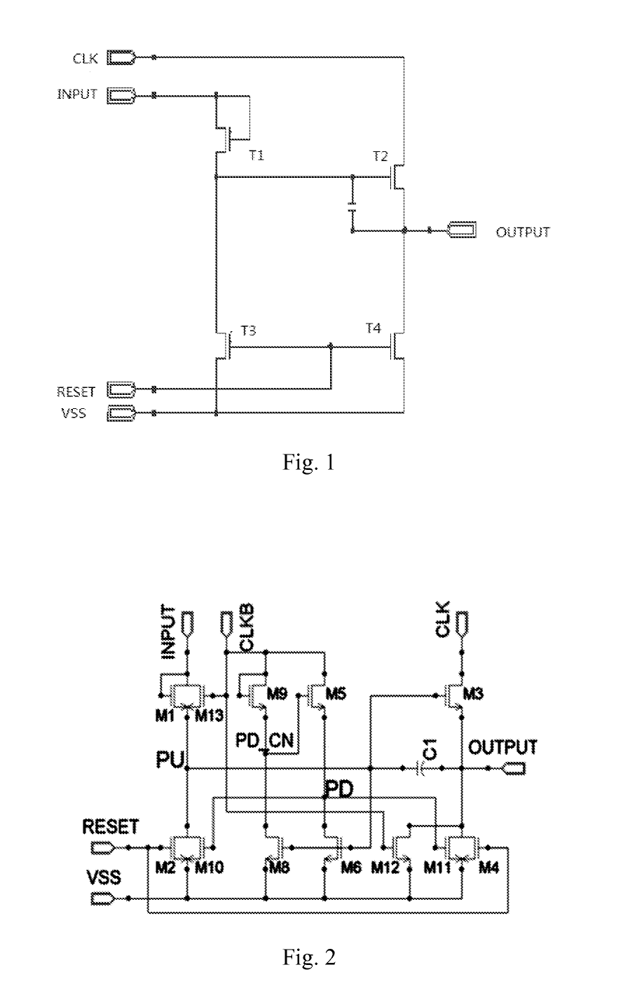

### DETAILED DESCRIPTION OF THE INVENTION

In order to enable the skilled person in the art to understand the technical solution of the present invention better, next, the shift register and the gate driving device of the present invention will be described in more details combined with the drawings and the specific embodiments.

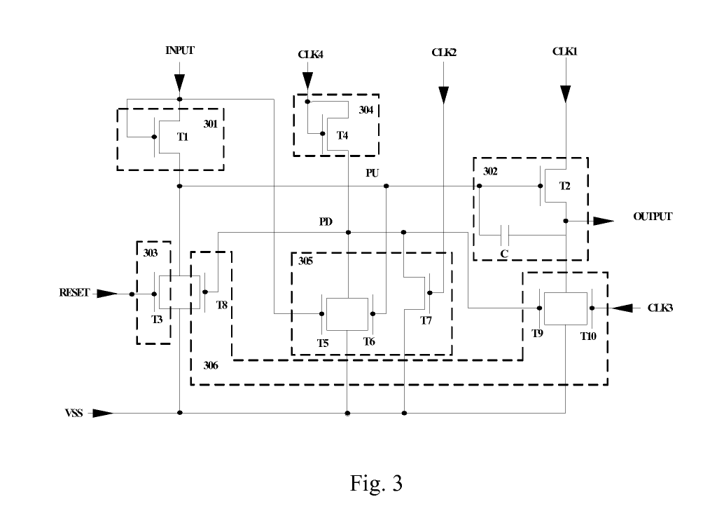

FIG. 3 is a structural schematic view of a shift register according to an embodiment of the present invention.

As shown in FIG. 3, the shift register according to the embodiment of the present invention may comprise: an input module 301, an output module 302, a reset module 303, a pull-up module 304, a first pull-down module 305 and a second pull-down module 306.

The input module 301, in response to an input signal INPUT, is arranged to provide the input signal INPUT to a pull-up node PU, wherein the pull-up node PU is an output node of the input module 301. The input module 301 may comprise a first thin film transistor T1, the gate and the source of the first thin film transistor being connected to the input end of the input module 301, the drain of the first thin film transistor being connected to the output node PU of the input module 301.

The output module 302 is arranged to store the input signal INPUT and in response to a voltage signal of the pull-up node PU, provide a first clock signal CLK1 to the output terminal of the shift register so as to genrate an output signal OUTPUT. The output module 302 may comprise: a second thin film transistor T2, the gate of the second thin film transistor being connected to the pull-up node PU, the source of the second thin film transistor being connected to the input end for the first clock signal CLK1, the drain of the second thin film transistor being connected to the output terminal; and a capacitor C connected between the pull-up node PU and the output terminal.

The reset module 303, in response to a reset signal RESET, is arranged to provide a level signal VSS to the pull-up node PU. The reset module 303 may comprise a third thin film transistor T3, the gate of the third thin film transistor being connected to the input end of the reset module, the source of the third thin film transistor being connected to the pull-up node PU, the drain of the third thin film transistor being connected to the input end for the level signal VSS.

The pull-up module 304, in response to a fourth clock signal CLK4, is arranged to provide the fourth clock signal CLK4 to the pull-down node PD, wherein the pull-down node PD is an output node of the pull-up module 304. The pull-up module 304 may comprise a fourth thin film transistor T4, the gate and the source of the fourth thin film transistor being connected to the input end for the fourth clock signal CLK4, the drain of the fourth thin film transistor being connected to the output node PD of the pull-up module 304.

The first pull-down module 305, in response to the input signal INPUT, the voltage of the pull-up node PU and a second clock signal CLK2, is arranged to provide the level signal VSS to the pull-down node PD. The first pull-down module 305 may comprise: a fifth thin film transistor T5, the gate of the fifth thin film transistor being connected to the input end of the input model 301, the source of the fifth thin film transistor being connected to the pull-down node PD, the drain of the fifth thin film transistor being connected to the input end for the level signal VSS; a sixth thin film transistor T6, the gate of the sixth thin film transistor being connected to the pull-up node PU, the source of the sixth thin film transistor being connected to the pull-down node PD, the drain of the sixth thin film transistor being connected to the input end for the level signal VSS; and a seventh thin film transistor T7, the gate of the seventh thin film transistor being connected to the input end for the second clock signal CLK2, the source of the seventh thin film transistor being connected to the pull-down node PD, the drain of the seventh thin film transistor being connected to the input end for the level signal VSS.

The second pull-down module 306, in response to the voltage of the pull-down node PD, is arranged to provide the level signal VSS to the pull-up node PU, and in response to the voltage of the pull-down node PD and a third clock signal CLK3, provide the level signal VSS to the output terminal. The second pull-down module 306 may comprise: an eighth thin film transistor T8, the gate of the eighth thin film transistor being connected to the pull-down node PD, the source of the eighth thin film transistor being connected to the pull-up node PU, the drain of the eighth thin film transistor being connected to the input end for the level signal VSS; a ninth thin film transistor T9, the gate of the ninth thin film transistor being connected to the pull-down node PD, the source of the ninth thin film transistor being connected to the output terminal, the drain of the ninth thin film transistor being connected to the input end for the level signal VSS; and a tenth thin film transistor T10, the gate of the tenth thin film transistor being connected to the input end for the third clock signal CLK3, the source of the tenth thin film transistor being connected to the output terminal, the drain of the tenth thin film transistor being connected to the input end for the level signal VSS.

According to an embodiment of the present invention, the first to the tenth thin film transistors T1 to T10 may be N-type thin film transistors. The N-type thin film transistor is turned on after a high level signal voltage is input at its gate, and is turned off after a low level signal voltage is input at its gate, hence, a low level signal can be used as the level signal VSS. Alternatively, the first to the tenth thin film transistors T1 to T10 may be P-type thin film transistors, and a high level signal can be used as the level signal VSS.

It should be noted that there is no explicit difference between the source and the drain of a thin film transistor, so the source of a thin film transistor mentioned in the present invention may be the drain of the thin film transistor, and the drain of a thin film transistor may be the source of the thin film transistor.

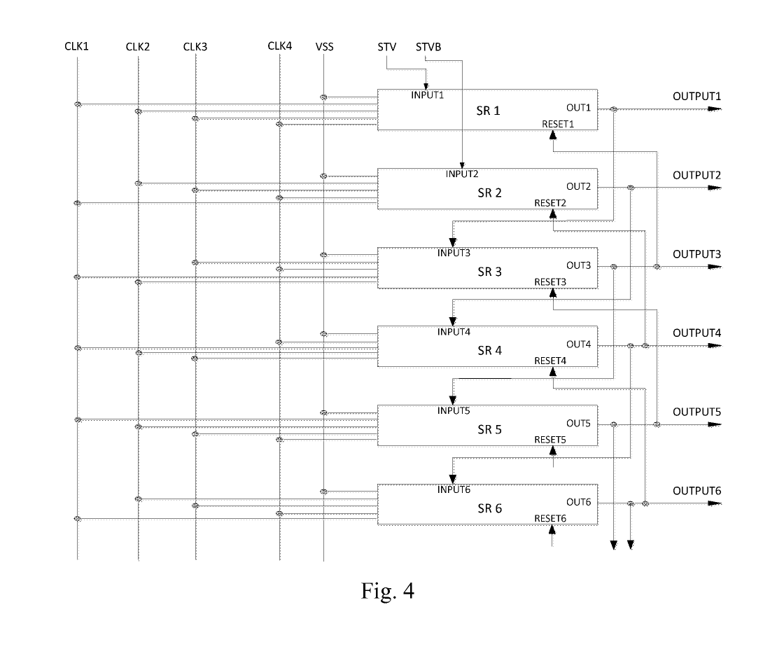

FIG. 4 is a structural schematic view of a gate driving device according to an embodiment of the present invention.

As shown in FIG. 4, the gate driving device according to an embodiment of the present invention may comprise cascaded shift registers according to respective embodiments of the present invention.

Each shift register may comprise the input end of the input module, the output terminal, the input end of the reset module, respective input ends for the first to the fourth clock signals and the input end for the level signal. In addition, FIG. 4 also shows a first start signal STV and a second start signal STVB as the input signals of the first stage of shift register SR1 and the second stage of shift register SR2 respectively. Each shift register can output a respective output signal.

For the sake of clarity, FIG. 4 shows a part of the whole gate driving device. FIG. 4 shows six shift registers, i.e., the first stage to the sixth stage of shift registers SR1 to SR6. The input end of the input module of the first stage of shift register SR1 is INPUT1, the output terminal is OUT1, the input end of the reset module is RESET1 and the output signal of the output terminal is OUPUT1; the input end of the input module of the second stage of shift register SR2 is INPUT2, the output terminal is OUT2, the input end of the reset module is RESET2 and the output signal of the output terminal is OUTPUT2, and so on.

The clock signals CLK1 to CLK4 serve as the first to the fourth clock signals of each shift register in turn. In the embodiment as shown in FIG. 4: the clock signal CLK1 is the first clock signal of the first stage of shift register SR1, the clock signal CLK2 is the second clock signal of the first stage of shift register SR1, the clock signal CLK3 is the third clock signal of the first stage of shift register SR1, the clock signal CLK4 is the fourth clock signal of the first stage of shift register SR1; the clock signal CLK2 is the first clock signal of the second stage of shift register SR2, the clock signal CLK3 is the second clock signal of the second stage of shift register SR2, the clock signal CLK4 is the third clock signal of the second stage of shift register SR2, the clock signal CLK1 is the fourth clock signal of the second stage of shift register SR2; the clock signal CLK3 is the first clock signal of the third stage of shift register SR3, the clock signal CLK4 is the second clock signal of the third stage of shift register SR3, the clock signal CLK1 is the third clock signal of the third stage of shift register SR3, the clock signal CLK2 is the fourth clock signal of the third stage of shift register SR3; the clock signal CLK4 is the first clock signal of the fourth stage of shift register SR4, the clock signal CLK1 is the second clock signal of the fourth stage of shift register SR4, the clock signal CLK2 is the third clock signal of the fourth stage of shift register SR4, the clock signal CLK3 is the fourth clock signal of the fourth stage of shift register SR4. The setting manner of the clock signals of the fifth stage of shift register SR5 is same as that of the first stage of shift register SR1, and the like.

In the embodiment as shown in FIG. 4, except that the input end INPUT1 of the input module of the first stage of shift register SR1 is connected with the first start signal STV, the input end of the input module of each odd stage of shift register is connected with the output terminal of the previous odd stage of shift register, and the input end of the reset module of each odd stage of shift register is connected with the output terminal of the next odd stage of shift register. That is to say, the input end INPUT1 of the input module of the first stage of shift register SR1 is connected to the first start signal STV, the input end INPUT3 of the input module of the third stage of shift register SR3 is connected with the output terminal OUT1 of the first stage of shift register SR1, and the input end RESET1 of the reset module of the first stage of shift register SR1 is connected with the output terminal OUT3 of the third stage of shift register SR3; the input end INPUT5 of the input module of the fifth shift register SR5 is connected with the output terminal OUT3 of the third stage of shift register SR3, and the input end RESET3 of the reset module of the third stage of shift register SR3 is connected with the output terminal OUT5 of the fifth stage of shift register SR5, and the like.

Moreover, except that the input end INPUT2 of the input module of the second stage of shift register SR2 is connected with the second start signal STVB, the input end of the input module of each even stage of shift register is connected with the output terminal of the previous even stage of shift register, and the input end of the reset module of each even stage of shift register is connected with the output terminal of the next even stage of shift register. That is to say, the input end INPUT2 of the input module of the second stage of shift register SR2 is connected with the second start signal STVB, the input end INPUT4 of the input module of the fourth stage of shift register SR4 is connected with the output terminal OUT2 of the second stage of shift register SR2, and the input end RESET2 of the reset module of the second stage of shift register SR2 is connected with the output terminal OUT4 of the fourth stage of shift register SR4; the input end INPUT6 of the input module of the sixth stage of shift register SR6 is connected with the output terminal OUT4 of the fourth stage of shift register SR4, and the input end RESET4 of the reset module of the fourth stage of shift register SR4 is connected with the output terminal OUT6 of the six stage of shift register SR6, and the like.

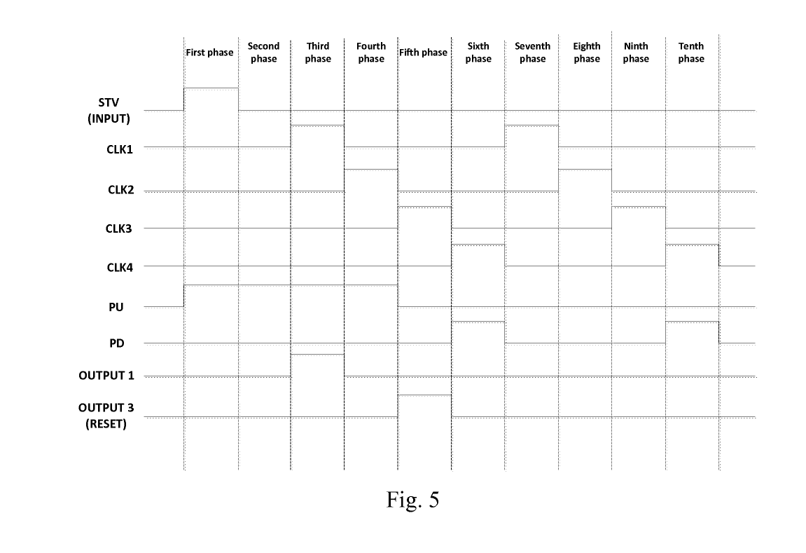

FIG. 5 is a logic timing diagram of a shift register according to an embodiment of the present invention.

Referring to FIG. 5, it shows changes of various signals in the shift register according to the embodiment of the present invention from the first phase to the tenth phase. Next, the driving process of the first stage of shift register SR1 will be introduced, the driving processes of the subsequent shift registers are similar as it, so they will not be repeated.

At the first phase, the input signal INPUT (i.e., the first start signal STV) is of high level, the first clock signal CLK1 to the fourth clock signal CLK4 are all of low level.

Since the input signal INPUT is of high level, the first thin film transistor T1 and the fifth thin film transistor T5 are turned on at the same time. Since the first thin film transistor T1 is turned on, a high level is introduced to the pull-up node PU, thereby the second thin film transitor T2 is turned on. Since the first clock signal CLK1 is of low level, the capactor C begins to be charged. Since the fifth thin film transistor T5 is turned on, a low level is introduced to the pull-down node PD, hence, the eight thin film transistor T8 and the ninth thin film transistor T9 will be turned off, thereby ensuring voltage stability of the pull-up node PU, and further ensuring voltage stability of the output signal OUTPUT1 of the output terminal OUT1. Since the reset signal RESET is the output signal OUTPUT3 of the output terminal OUT3 of the third stage of shift register SR3, and the output signal OUTPUT3 of the output terminal OUT3 of the third stage of shift register SR3 is of low level, hence, the reset signal RESET is of low level, and the third thin film transistor T3 is turned off. Since the second clock signal CLK2 is of low level, the seventh thin film transistor T7 is turned off. Since the third clock signal CLK3 is of low level, the tenth thin film transistor T10 is turned off. Since the fourth clock signal CLK4 is of low level, the fourth thin film transistor T4 is turned off. Here, since the first clock signal CLK1 is of low level, and the second thin film transistor T2 is turned on, hence, the output signal OUTPUT1 of the output terminal OUT1 is of low level.

At the second phase, the input signal INPUT is of low level, the first clock signal CLK1 to the fourth clock signal CLK4 are all of low level.

Since the input signal INPUT is of low level, the first thin film transistor T1 and the fifth thin film transistor T5 are turned off. Since the capacitor C is charged at the first phase, bootstrapping occurs at the second phase, the potential of the pull-up node PU is promoted continuously, such that the pull-up node PU persists on a high potential, thereby the second thin film transistor T2 is turned on. Since the fifth thin film transistor T5 is turned off, the pull-down node PD persists on a low level, hence, the eighth thin film transistor T8 and the ninth thin film transistor T9 are kept in the turn-off state, thereby continuously ensuring voltage stability of the pull-up node PU, and further ensuring voltage stability of the output signal OUTPUT1 of the output terminal OUT1. Since the output signal OUTPUT3 of the output terminal OUT3 of the third stage of shift register SR3 is of low level, the reset signal RESET is of low level. Since the second clock signal CLK2 is of low level, the seventh thin film transistor T7 is turned off. Since the third clock signal CLK3 is of low level, the tenth thin film transistor T10 is turned off. Since the fourth clock signal CLK4 is of low level, the fourth thin film transistor T4 is turned off. Here, since the first clock signal CLK1 is of low level and the second thin film transistor T2 is turned on, the output signal OUTPUT1 of the output terminal OUT1 is of low level.

At the third phase, the input signal INPUT is of low level, the first clock signal CLK1 is of high level, the second clock signal CLK2 to the fourth clock signal are all of low level.

Since the input signal INPUT is of low level, the first thin film transistor T1 and the fifth thin film transistor T5 are turned off. Since the capacitor C is charged at the first phase, bootstrapping occurs at the third phase, the potential of the pull-up node PU is promoted continuously, such that the pull-up node PU persists on a high potential, thereby the second thin film transistor T2 is turned on. Since the fifth thin film transistor T5 is turned off, the pull-down node PD persists on a low level, hence, the eighth thin film transistor T8 and the ninth thin film transistor T9 are kept in the turn-off state, thereby continuously ensuring voltage stability of the pull-up node PU, and further ensuring voltage stability of the output signal OUTPUT1 of the output terminal OUT1. Since the output signal OUTPUT3 of the output terminal OUT3 of the third stage of shift register SR3 is of low level, the reset signal RESET is of low level. Since the second clock signal CLK2 is of low level, the seventh thin film transistor T7 is turned off. Since the third clock signal CLK3 is of low level, the tenth thin film transistor T10 is turned off. Since the fourth clock signal CLK4 is of low level, the fourth thin film transistor T4 is turned off. Here, since the first clock signal CLK1 is of high level and the second thin film transistor T2 is turned on, the output signal OUTPUT1 of the output terminal OUT1 is of high level.

At the fourth phase, the input signal INPUT is of low level, the first clock signal CLK1, the third clock signal CLK3 and the fourth clock signal CLK4 are of low level, the second clock signal CLK2 is of high level.

Since the input signal INPUT is of low level, the first thin film transistor T1 and the fifth thin film transistor T5 are turned off. Since the output signal OUTPUT3 of the output terminal OUT3 of the third stage of shift register SR3 is of low level, the reset signal RESET is of low level. Since the second clock signal CLK2 is of high level, the seventh thin film transistor T7 is turned on, a low level is introduced to the pull-down node PD, which ensures that the pull-down node PD keeps at a low level, thereby keeping the eighth thin film transistor T8 and the ninth thin film transistor T9 in the turn-off state, so that the pull-up node PU is kept in the high level state, and the second thin film transistor T2 is turned on. Since the third clock signal CLK3 is of low level, the tenth thin film transistor T10 is turned off. Since the fourth clock signal CLK4 is of low level, the fourth thin film transistor T4 is turned off. Since the input signal INPUT is of low level, the first thin film transistor T1 and the fifth thin film transistor T5 are both turned off. Since the first clock signal CLK1 is of low level and the second thin film transistor T2 is turned on, the output signal OUTPUT1 of the output terminal OUT1 is of low level.

At the fifth phase, the input signal INPUT is of low level, the first clock signal CLK1, the second clock signal CLK2 and the fourth clock signal CLK4 are of low level, the third clock signal CLK3 is of high level.

Since the input signal INPUT is of low level, the first thin film transistor T1 and the fifth thin film transistor T5 are turned off. Since the output signal OUTPUT3 of the output terminal OUT3 of the third stage of shift register SR3 is of high level (the process in which the output signal OUTPUT3 of the output terminal OUT3 of the third stage of shift register SR3 is of high level is similar as the process in which the output signal OUTPUT1 of the output terminal OUT1 of the first stage of shift register SR1 is of high level, the difference lies in that the output signal OUTPUT1 of the first stage of shift register SR1 serves as the input signal INPUT of the third stage of shift register SR3, and the respective clock signals CLK1 to CLK4 are set correspondingly, see FIG. 4), the reset signal RESET is of high level, the third thin film transistor T3 is turned on, and a low level is introduced to the pull-up node PU, such that the pull-up node PU is discharged, hence, the second thin film transistor T2 and the six thin film transistor T6 are turned off. The pull-down node PD keeps at a low level, thereby keeping the eighth thin film transistor T8 and the ninth thin film transistor T9 in the turn-off state. Since the second clock signal CLK2 is of low level, the seventh thin film transistor T7 is turned off. Since the third clock signal CLK3 is of high level, the tenth thin film transistor T10 is turned on, thereby a low level is introduced to the output terminal OUT1, such that the output terminal OUT1 is discharged. Since the fourth clock signal CLK4 is of low level, the fourth thin film transistor T4 is turned off. Here, since the tenth thin film transistor T10 is turned on, the output signal OUTPUT1 of the output terminal OUT1 is of low level.

At the six phase, the input signal INPUT is of low level, the first clock signal CLK1 to the third clock signal CLK3 are of low level, the fourth clock signal CLK4 is of high level.

Since the input signal INPUT is of low level, the first thin film transistor T1 and the fifth thin film transistor T5 are turned off. Since the output signal OUTPUT3 of the output terminal OUT3 of the third stage of shift register SR3 is of low level, the reset signal RESET is of low level. Since the second clock signal CLK2 is of low level, the seventh thin film transistor T7 is turned off. Since the third clock signal CLK3 is of low level, the tenth thin film transistor T10 is turned off. Since the fourth clock signal CLK4 is of high level, the fourth thin film transistor T4 is turned on, a high level is introduced to the pull-down node PD, such that the pull-down node PD is in a high level state, hence, the eighth thin film transistor T8 and the ninth thin film transistor T9 are turned on simultaneously. Since the eighth thin film transistor T8 is turned on, a low level is introduced to the pull-up node PU, hence, the second thin film transistor T2 and the sixth thin film transistor T6 are turned off. Here, since the ninth thin film transistor T9 is turned on, the output signal OUTPUT1 of the output terminal OUT1 is of low level.

The output signal OUTPUT1 of the first stage of shift register SR1 at the third phase is of high level, it serves as the input signal INPUT of the third stage of shift register SR3, hence, the output signal OUTPUT3 of the third stage of shift register SR3 at the fifth phase is of high level, and serves as the reset signal RESET of the first stage of shift register SR1.

The driving process of the even stage of shift register is similar as the driving process of the odd stage of shift register, the difference lies in that the second start signal STVB serves as the input signal INPUT of the second stage of shift register SR2, and the high level state of the second start signal STVB is one phase later than the high level state of the first start signal STV.

In addition, the first to the tenth thin film transistors T1 to T10 may also be P-type thin film transistors. The P-type thin film transistor is turned on after a low level signal is input at its gate, and turned off after a high level signal is input at its gate, here, a high level signal can be used as the level signal VSS, and the circuit structure of this embodiment is changed correspondingly.

Therefore, the present invention is not limited to the circuit structure in the embodiment, other circuit strutures that can implement the same functions may also be used.

Thus it can be seen that the shift register according to the embodiment of the present invention adopts the manner of inputting four clock signals, and the duty cycle of each clock signal is 25%, thereby mitigating the drift of the threshold voltage of the thin film transistor. In addition, when the output signal of the output terminal is of low level, the second clock signal CLK2, the third clock signal CLK3 and the fourth clock signal CLK4 of high levels are provided successively, so as to realize discharge of the output terminal. That is to say, when the second clock signal CLK2 is of high level, the seventh thin film transistor T7 is turned on, the pull-down node PD is kept at a low level, thereby keeping the eight thin film transistor T8 and the ninth thin film transistor T9 to be turned off, such that the pull-up node PU persists on a high level, thereby the second thin film transistor T2 is turned on, since the first clock signal CLK1 is of low level here, discharge of the output terminal is realized; when the third clock signal CLK3 is of high level, the tenth thin film transistor T10 is turned on, since the pull-up node PU is of low level at the fifth phase, the second thin film transistor T2 is turned off, however, the tenth thin film transistor T10 is turned on here, thereby, the discharge of the output terminal is realized; when the fourth clock signal CLK4 is of high level, the fourth thin film transistor T4 is turned on, the pull-down node PD is of high level, such that the ninth thin film transistor T9 is turned on, since the pull-up node PU is of low level at the sixth phase, the second thin film transistor T2 is turned off, however, the ninth thin film transistor T9 is turned on here, thereby the discharge of the output terminal is realized. The discharge of the output terminal not only ensures that the output signal OUTPUT contains relatively low noise, but also increases life time of the thin film transistor.

To sum up, in the shift register and the gate driving device according to the embodiment of the present invention, the odd and even cross-driven shift register adopts the manner of inputting four clock signals, and the duty cycle of each clock signal is 25%, thereby mitigating drift of the threshold voltage of the thin film transistor. In addition, since the amount of the thin film transistors is reduced, the circuit structure is simplified, so as to meet the requirement of the small-size panel display on narrow frames. By keeping the voltage of the pull-up node in the shift register stable, the stability of the output signal is ensured.

Apparently, the skilled person in the art can make various modifications and variants to the present invention without departing from the spirit and scope of the present invention. Thus, if these modifications and variants of the present invention fall within the scopes of the claims and the equivalent technologies of the present invention, the present invention also intends to cover these modifications and variants.

1. A shift register, comprising: an input module, an output module, a reset module, a pull-up module, a first pull-down module and a second pull-down module, wherein,
the input module, in response to an input signal, is arranged to provide the input signal to a pull-up node, wherein the pull-up node is an output node of the input module,
the output module is arranged to store the input signal and in response to a voltage of the pull-up node, provide a first clock signal to an output terminal of the shift register,
the reset module, in response to a reset signal, is arranged to provide a level signal to the pull-up node,
the pull-up module, in response to a fourth clock signal, is arranged to provide the fourth clock signal to a pull-down node, wherein the pull-down node is an output node of the pull-up module,
the first pull-down module, in response to the input signal, the voltage of the pull-up node and a second clock signal, is arranged to provide the level signal to the pull-down node,
the second pull-down module, in response to the voltage of the pull-down node, is arranged to provide the level signal to the pull-up node, and in response to the voltage of the pull-down node and a third clock signal, provide the level signal to the output terminal.

2. The shift register according to claim 1, wherein the input module comprises a first thin film transistor, a gate and a source of the first thin film transistor being connected to an input end of the input module, a drain of the first thin film transistor being connected to the output node of the input module.

3. The shift register according to claim 1, wherein the output module comprises:
a second thin film transistor, a gate of the second thin film transistor being connected to the pull-up node, a source of the second thin film transistor being connected to an input end for the first clock signal, a drain of the second thin film transistor being connected to the output terminal; and
a capacitor connected between the pull-up node and the output terminal.

4. The shift register according to claim 1, wherein the reset module comprises a third thin film transistor, a gate of the third thin film transistor being connected to an input end of the reset module, a source of the third thin film transistor being connected to the pull-up node, a drain of the third thin film transistor being connected to an input end for the level signal.

5. The shift register according to claim 1, wherein the pull-up module comprises a fourth thin film transistor, a gate and a source of the fourth thin film transistor being connected to an input end for the fourth clock signal, a drain of the fourth thin film transistor being connected to the output node of the pull-up module.

6. The shift register according to claim 1, wherein the first pull-down module comprises:
a fifth thin film transistor, a gate of the fifth thin film transistor being connected to the input end of the input module, a source of the fifth thin film transistor being connected to the pull-down node, a drain of the fifth thin film transistor being connected to the input end for the level signal;
a sixth thin film transistor, a gate of the sixth thin film transistor being connected to the pull-up node, a source of the sixth thin film transistor being connected to the pull-down node, a drain of the sixth thin film transistor being connected to the input end for the level signal; and
a seventh thin film transistor, a gate of the seventh thin film transistor being connected to an input end for the second clock signal, a source of the seventh thin film transistor being connected to the pull-down node, a drain of the seventh thin film transistor being connected to the input end for the level signal.

7. The shift register according to claim 1, wherein the second pull-down module comprises:
an eighth thin film transistor, a gate of the eighth thin film transistor being connected to the pull-down node, a source of the eighth thin film transistor being connected to the pull-up node, a drain of the eighth thin film transistor being connected to the input end for the level signal;
a ninth thin film transistor, a gate of the ninth thin film transistor being connected to the pull-down node, a source of the ninth thin film transistor being connected to the output terminal, a drain of the ninth thin film transistor being connected to the input end for the level signal; and
a tenth thin film transistor, a gate of the tenth thin film transistor being connected to an input end for the third clock signal, a source of the tenth thin film transistor being connected to the output terminal, a drain of the tenth thin film transistor being connected to the input end for the level signal.

8. The shift register according to claim 1, wherein a duty cycle of each of the first clock signal to the fourth clock signal is 25%, and the first clock signal to the fourth clock signal are of high level successively.

9. A gate driving device, comprising a cascaded shift register, the shift register comprises: an input module, an output module, a reset module, a pull-up module, a first pull-down module and a second pull-down module, wherein,
the input module, in response to an input signal, is arranged to provide the input signal to a pull-up node, wherein the pull-up node is an output node of the input module,
the output module is arranged to store the input signal and in response to a voltage of the pull-up node, provide a first clock signal to an output terminal of the shift register,
the reset module, in response to a reset signal, is arranged to provide a level signal to the pull-up node,
the pull-up module, in response to a fourth clock signal, is arranged to provide the fourth clock signal to a pull-down node, wherein the pull-down node is an output node of the pull-up module,
the first pull-down module, in response to the input signal, the voltage of the pull-up node and a second clock signal, is arranged to provide the level signal to the pull-down node,
the second pull-down module, in response to the voltage of the pull-down node, is arranged to provide the level signal to the pull-up node, and in response to the voltage of the pull-down node and a third clock signal, provide the level signal to the output terminal.

10. The gate driving device according to claim 9, wherein the input module comprises a first thin film transistor, a gate and a source of the first thin film transistor being connected to an input end of the input module, a drain of the first thin film transistor being connected to the output node of the input module.

11. The gate driving device according to claim 9, wherein the output module comprises:
a second thin film transistor, a gate of the second thin film transistor being connected to the pull-up node, a source of the second thin film transistor being connected to an input end for the first clock signal, a drain of the second thin film transistor being connected to the output terminal; and
a capacitor connected between the pull-up node and the output terminal.

12. The gate driving device according to claim 9, wherein the reset module comprises a third thin film transistor, a gate of the third thin film transistor being connected to an input end of the reset module, a source of the third thin film transistor being connected to the pull-up node, a drain of the third thin film transistor being connected to an input end for the level signal.

13. The gate driving device according to claim 9, wherein the pull-up module comprises a fourth thin film transistor, a gate and a source of the fourth thin film transistor being connected to an input end for the fourth clock signal, a drain of the fourth thin film transistor being connected to the output node of the pull-up module.

14. The gate driving device according to claim 9, wherein the first pull-down module comprises:
a fifth thin film transistor, a gate of the fifth thin film transistor being connected to the input end of the input module, a source of the fifth thin film transistor being connected to the pull-down node, a drain of the fifth thin film transistor being connected to the input end for the level signal;
a sixth thin film transistor, a gate of the sixth thin film transistor being connected to the pull-up node, a source of the sixth thin film transistor being connected to the pull-down node, a drain of the sixth thin film transistor being connected to the input end for the level signal; and
a seventh thin film transistor, a gate of the seventh thin film transistor being connected to an input end for the second clock signal, a source of the seventh thin film transistor being connected to the pull-down node, a drain of the seventh thin film transistor being connected to the input end for the level signal.

15. The gate driving device according to claim 9, wherein the second pull-down module comprises:
an eighth thin film transistor, a gate of the eighth thin film transistor being connected to the pull-down node, a source of the eighth thin film transistor being connected to the pull-up node, a drain of the eighth thin film transistor being connected to the input end for the level signal;
a ninth thin film transistor, a gate of the ninth thin film transistor being connected to the pull-down node, a source of the ninth thin film transistor being connected to the output terminal, a drain of the ninth thin film transistor being connected to the input end for the level signal; and
a tenth thin film transistor, a gate of the tenth thin film transistor being connected to an input end for the third clock signal, a source of the tenth thin film transistor being connected to the output terminal, a drain of the tenth thin film transistor being connected to the input end for the level signal.

16. The gate driving device according to claim 9, wherein a duty cycle of each of the first clock signal to the fourth clock signal is 25%, and the first clock signal to the fourth clock signal are of high level successively.

17. The gate driving device according to claim 9, wherein
except that an input end of an input module of a first stage of shift register is connected with a first start signal, the input end of the input module of each odd stage of shift register is connected with the output terminal of a previous odd stage of shift register, and the input end of the reset module of each odd stage of shift register is connected with the output terminal of a next odd stage of shift register, and
except that an input end of an input module of a second stage of shift register is connected with a second start signal, the input end of the input module of each even stage of shift register is connected with the output terminal of a previous even stage of shift register, and the input end of the reset module of each even stage of shift register is connected with the output terminal of a next even stage of shift register.
